(19) United States
(12) Patent Application Publication
(10) Pub. No.: US 2026/0357472 A1
(43) Pub. Date: Nov. 12, 2026

(54) EPITAXIAL METAL ELECTRODEPOSITION CONTROLLED BY GRAPHENE LAYER THICKNESS

(71) Applicant: Georgia Tech Research Corporation, Atlanta, GA (US)

(72) Inventors: Matthew T. McDowell, Atlanta, GA (US); Salem Clay Wright, Atlanta, GA (US)

(21) Appl. No.: 19/669,620

(22) Filed: May 6, 2026

Related U.S. Application Data
(60) Provisional application No. 63/801,889, filed on May 8, 2025.

(51) Int. Cl. C30B 7/12; C23C 16/26; C23C 28/00; C25D 5/00; C25D 5/54; C30B 7/00; C30B 29/02

(52) U.S. Cl. CPC C30B 7/12; C23C 16/26; C23C 28/322; C23C 28/3225; C23C 28/34; C25D 5/54; C25D 5/617; C30B 7/005; C30B 29/02

(57) ABSTRACT

Disclosed are methods for controlling epitaxial metal growth, methods for forming thin films, and metal thin films. The methods can include selecting a metal and electrodepositing the metal on a graphene bilayer or monolayer of a substrate. The substrate can include a graphene bilayer or monolayer deposited on a base layer. The base layer can be a metal foil such as copper.

### CROSS-REFERENCE TO RELATED APPLICATIONS

This application claims the benefit of U.S. Provisional Application No. 63/801,889, filed May 8, 2025, the entire contents of which is hereby incorporated herein by reference.

### STATEMENT REGARDING FEDERALLY SPONSORED RESEARCH OR DEVELOPMENT

This invention was made with government support under Grant No. N00014-19-1-2195 awarded by the Navy Office of Naval Research and Grant No. ECCS-2025462 awarded by the National Science Foundation. The government has certain rights in the invention.

### BACKGROUND

Control over the morphology and structure of metals during electrodeposition is necessary for a variety of applications such as integrated circuits and batteries. Graphene plays an integral role in these applications, but precise control over graphene deposition and the resulting electrochemical effects has been elusive. Accordingly, needs exist for methods for controlling epitaxial metal deposition and graphene layer thickness. It is to the provision of meeting these and other needs that the present invention is primarily directed.

### SUMMARY

Embodiments of the present disclosure provide for methods of controlling epitaxial growth, metal thin films, and methods for making metal thin films or electrodes.

An embodiment of the present disclosure includes method of controlling epitaxial metal growth, the method comprising selecting a metal, then selecting a low-defect density turbostratic graphene substrate based on a desired crystallographic influence on the metal. The substrate can include a base layer with a graphene bilayer or a graphene monolayer deposited on the base layer. The method further includes depositing the metal on the graphene bilayer or the graphene monolayer.

An embodiment of the present disclosure also includes a metal thin film that includes a low-defect density turbostratic graphene substrate. The substrate can include a base layer and a graphene bilayer or a graphene monolayer deposited on the base layer. A metal layer can be electrodeposited on the graphene bilayer or the graphene monolayer. The metal is crystallographically aligned to the base layer.

An embodiment of the present disclosure also includes a method of making a metal thin film. The method can include selecting a metal and providing a graphene substrate. The substrate can include a first graphene monolayer grown on a base layer by chemical vapor deposition. The method can further include electrodepositing the metal on the first graphene monolayer.

These and other aspects, objects, features, and embodiments will become apparent to a person of ordinary skill in the art upon consideration of the following detailed description of illustrative embodiments exemplifying the best mode as presently perceived.

### BRIEF DESCRIPTION OF THE DRAWINGS

For a more complete understanding of the embodiments and the advantages thereof, reference is now made to the following description, in conjunction with the accompanying figures briefly described as follows:

FIGS. 1A and 1B are schematic diagrams of metal thin films comprising a graphene monolayer and graphene bilayer, respectively, according to various example embodiments;

FIGS. 2A-2C provide Raman spectra information for thin films according to various example embodiments;

FIGS. 3A-3E are SEM images of Cu electrodeposited on bare Cu, monolayer graphene, bilayer graphene, trilayer graphene, and graphite, respectively, according to various example embodiments. FIGS. 3F-3J are SEM images of Zn electrodeposited on bare Cu, monolayer graphene, bilayer graphene, trilayer graphene, and graphite, respectively, according to various example embodiments.

The drawings illustrate only example embodiments and are therefore not to be considered limiting of the scope described herein, as other equally effective embodiments are within the scope and spirit of this disclosure. The elements and features shown in the drawings are not necessarily drawn to scale, emphasis instead being placed upon clearly illustrating the principles of the embodiments. Additionally, certain dimensions may be exaggerated to help visually convey certain principles. In the drawings, similar reference numerals between figures designate like or corresponding, but not necessarily the same, elements.

### DETAILED DESCRIPTION

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting, since the scope of the present disclosure will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Embodiments of the present disclosure will employ, unless otherwise indicated, techniques of chemistry, material science, and the like, which are within the skill of the art.

The following examples are put forth so as to provide those of ordinary skill in the art with a complete disclosure and description of how to perform the methods and use the devices and methods disclosed and claimed herein. Efforts have been made to ensure accuracy with respect to numbers (e.g., amounts, temperature, etc.), but some errors and deviations should be accounted for. Unless indicated otherwise, parts are parts by weight, temperature is in °C, and pressure is at or near atmospheric. Standard temperature and pressure are defined as 20 °C and 1 atmosphere.

Before the embodiments of the present disclosure are described in detail, it is to be understood that, unless otherwise indicated, the present disclosure is not limited to particular materials, reagents, reaction materials, manufacturing processes, or the like, as such can vary. It is also to be understood that the terminology used herein is for purposes of describing particular embodiments only and is not intended to be limiting. It is also possible in the present disclosure that steps can be executed in different sequence where this is logically possible.

It must be noted that, as used in the specification and the appended claims, the singular forms “a,” “an,” and “the” include plural referents unless the context clearly dictates otherwise.

### Abbreviations

The following abbreviations may be used in the present disclosure: CVD (chemical vapor deposition); DFT (Density Functional Theory); EBSD (electron backscatter diffraction); EIS (electrochemical impedance spectroscopy); FFT(fast Fourier transform analysis); MOCVD (metal-organic chemical vapor deposition); SAED (selected area electron diffraction); and TEM (transmission electron microscopy).

### Definitions

“Graphene monolayer,” as used herein, refers to a layer that is one carbon atom thick.

### General Discussion

In accordance with the purpose(s) of the present disclosure, as embodied and broadly described herein, embodiments of the present disclosure, in some aspects, relate to

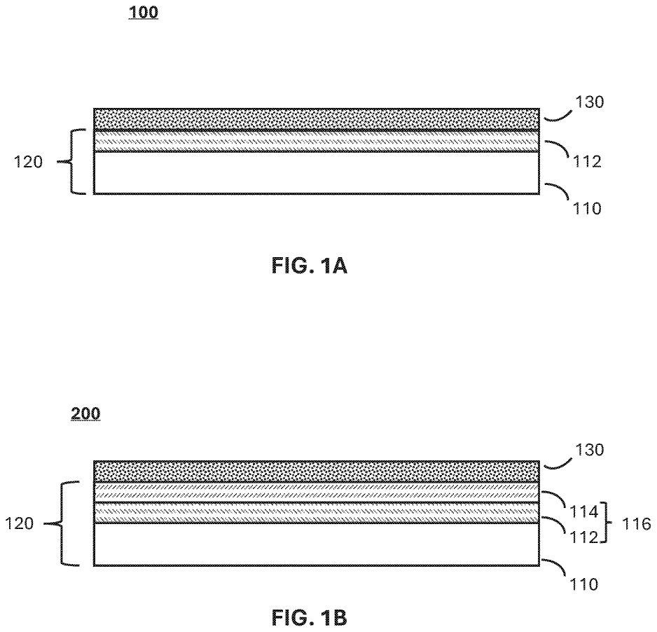

In general, embodiments of the present disclosure provide for methods for controlling epitaxial metal growth, methods for forming thin films, and metal thin films. Schematic illustrations of metal thin films comprising a graphene monolayer and graphene bilayer are shown in FIGS. 1A and 1B, respectively.

The methods for controlling epitaxial metal growth and methods for forming metal thin films 100,200 can include selecting a metal and depositing the metal 130 on a substrate 120. The substrate can include a graphene bilayer 116 or monolayer 112 deposited on a base layer 110, where the metal 130 is deposited on the graphene bilayer 116 or monolayer 112. The base layer 110 can be a metal foil such as copper. Other base layer 110 materials can also be used, provided that the material can receive another material electrodeposited on top that has an identical or similar crystallographic structure and lattice spacing as the base layer to generate the remote epitaxy effect. For example, other metals, including but not limited to Ni, Fe, and Au can be used as a base layer 110.

An embodiment of the present disclosure includes a metal thin film 100, 200 comprising a low-defect density turbostratic graphene substrate 120. The substrate can include a base layer 110 and a graphene bilayer 116 or a graphene monolayer 112 deposited on the base layer. A metal layer 130 is electrodeposited on the graphene bilayer 116 or the graphene monolayer 112, and the metal 130 is crystallographically aligned to the base layer 110.

In various embodiments, the metal is zinc or copper.

The metal layer thickness can be based on a duration of the homoepitaxial growth after the underlying graphene substrate is fully coated.

In some embodiments, the method further includes depositing a first graphene monolayer 112 on the base layer 110. The depositing can be achieved by such as growing the first graphene monolayer on the base layer via chemical vapor deposition.

In some embodiments, the graphene bilayer 116 can then be formed by transferring a second monolayer of graphene 114 onto the graphene monlolayer 112 using polymer-assisted transfer or other suitable method, wherein the second monolayer 114 is transferred onto the first monolayer 112 without intentional alignment.

Advantageously, the graphene monolayer 112 or graphene bilayer 116 prevents oxidation of the base layer 110.

Advantageously, the graphene bilayer is not AB-stacked graphene, no alignment between the graphene layers is required, resulting in a base layer without a native oxide layer.

The method of making the thin films is simpler than those used to generate AB-stacked graphene. AB-stacked graphene is the lowest energy configuration of multilayer graphene. To achieve AB-stacked graphene, either the growth of graphene layers must be precisely controlled using CVD, which is difficult or a transferred graphene layer must be precisely aligned. The methods provided herein allow for a transfer in which no alignment between graphene layers is required, achieving a base layer comprising a metal of high crystallinity on which a monolayer of graphene has been grown. An additional monolayer can then be added on top of the metal/graphene monolayer to form a bilayer, which promotes epitaxial growth to the underlying substrate during electrodeposition. Further monolayers can be added one-by-one if desired to prevent epitaxial growth with the underlying substrate.

The methods described herein use PMMA-assisted transfer steps of monolayer graphene. Other methods that utilize turbostratic graphene synthesize the graphene directly instead, which ultimately is less precise in terms of layer thickness. Using the methods herein, one can create an electrode with an exact number of graphene (e.g., two layers of graphene, three layers), which cannot be achieved with direct synthesis. Uniquely, the electrodes and metal thin films produced using the method provided herein can achieve epitaxial growth where the epitaxy occurs between the deposited metal and the underlying substrate on which the first monolayer of graphene was synthesized. As provided above, the underlying substrate, or base layer can be such as copper or other highly crystalline metal substrates. The highly crystalline substrates can either be those that do not have a native oxide or those that have the native oxide removed and can have graphene transferred to them without the layer growing back quickly.

Advantageously, the method is rapid and scalable. Because the graphene layers are randomly oriented relative to each other, ensuring a precise alignment of the orientation of distinct graphene layers is not necessary. In previous methods, precise angles between layers are required, which is difficult to achieve experimentally. The method provided herein utilizes standard polymer-based graphene transfer, resulting in a simplified process that generates a low-defect product.

Unexpectedly, the surface morphology of the metal deposited on the graphene bilayer or the graphene monolayer differs from the surface morphology of a metal deposited on trilayer graphene or graphite, even where the thickness of the metal layer is the same. The underlying base layer influences the structure of the deposited metal, but the influence is dependent on the thickness of the graphene layer or layers between the base layer and the metal layer, not solely due to the graphene layers. The fact that the graphene is turbostratic indicates that the effect originates from the base layer with the graphene serving as an intermediary. Thus, the methods described herein produce thin films that possess properties different from previous graphene thin films.

Advantageously, in the methods described herein, the graphene is transferred without intentional alignment to produce graphene layers that are randomly rotated relative to each other, which is the signature of turbostratic graphene. Turbostratic graphene can be identified by the presence of low-intensity modes in the 1700-2300 cm⁻¹ region of the Raman spectra. The thin films also the presence of the M-band and a relatively low I_{2D}/I_{G} ratio, which is suggestive of low defect density turbostratic graphene.

Advantageously, thin films produced in accordance with the described method exhibit remote epitaxial properties with low defect density.

The methods provided herein can also be used to make metal thin films.

### Substrates

The base layer 110 of the substrate can be metal or a metal foil. In some embodiments, the base layer can comprise a coating on the opposite surface from the surface deposited with a graphene mono- or bilayer. Alternatively, the base layer 110 can be deposited on or bound to another substrate. For example, the base layer can be deposited on or bound to another metal, a polymer, or other material. In preferred embodiments, the base layer 110 has high crystallinity enabled by annealing or other surface treatments. The base layer can be an alloy or a metal.

In a particular embodiment, the base layer is a copper foil.

The base layer can comprise one or more layers or sublayers. The layers and sublayers can be the same as or different from one another. Each of the layers or sublayers may have a suitable thickness appropriate for a desired application. For example, each of the layers or sublayers can have a thickness of from about 10 nm to about 100 μm, such as from 10 nm to 50 nm, from 10 nm to 100 nm, from 10 nm to 1 μm, from 10 nm to 5 μm, from 10 nm to 10 μm, from 10 nm to 50 μm, from 10 nm to 100 μm, from 50 nm to 100 nm, from 50 nm to 500 nm, from 50 nm to 1 μm, from 50 nm to 5 μm, from 50 nm to 10 μm, from 50 nm to 50 μm, from 50 nm to 100 μm, from 100 nm to 500 nm, from 100 nm to 1 μm, from 100 nm to 5 μm, from 100 nm to 10 μm, from 100 nm to 50 μm, from 100 nm to 100 μm, from 500 nm to 1 μm, from 500 nm to 5 μm, from 500 nm to 10 μm, from 500 nm to 50 μm, from 500 nm to 100 μm, from 1 μm to 5 μm, from 1 μm to 10 μm, from 1 μm to 50 μm, from 1 μm to 100 μm, from 5 μm to 10 μm, from 5 μm to 50 μm, from 5 μm to 100 μm, from 10 μm to 50 μm, from 10 μm to 100 μm, or from 50 μm to 100 μm.

The graphene bilayer or graphene monolayer can be deposited on the base layer using any method suitable for controlled deposition. Such methods can include but are not limited to electrodeposition, chemical vapor deposition, polymer-assisted transfer, evaporation deposition, chemical deposition process, atomic layer deposition, electroplating, and the like. The first layer of the graphene bilayer and the second layer of the graphene bilayer can be deposited using the same method or a different method. For example, the first layer could be deposited on the base layer using chemical vapor deposition and the second layer could be added to the first layer using polymer-assisted transfer.

In some embodiments, the base layer could comprise a metal deposited on a stack of graphene layers with more metal deposited on the opposite side.

As can be appreciated by a person having ordinary skill in the art, the base layer can have any area. In other words, the base layer can have a length and width suitable for a desired application. In a particular application, a large foil comprising a graphene monolayer with one or more additional graphene monolayers transferred onto the graphene monolayer as provided herein could be used in a cylindrical battery.

### EXAMPLES

Now having described the embodiments of the disclosure, in general, the examples describe some additional embodiments. While embodiments of the present disclosure are described in connection with the example and the corresponding text and figures, there is no intent to limit embodiments of the disclosure to these descriptions. On the contrary, the intent is to cover all alternatives, modifications, and equivalents included within the spirit and scope of embodiments of the present disclosure.

### Example 1

### Introduction

Control over the morphology and structure of metals during electrodeposition is necessary for a variety of applications. For instance, to deposit copper with low sheet resistance for integrated circuits, careful consideration is given to the orientation and microstructure of electroplated copper. Coatings for corrosion protection also heavily rely on the morphology and structure of the electrodeposited films to achieve desired traits like hydrophobicity and resilience. Nanostructured electrocatalysts prepared using electrodeposition can take advantage of electrochemical parameters to control surface faceting and thus selectivity and activity. Additionally, electrodeposition is the mechanism used by battery chemistries with metal anodes. Because electrodeposition is sensitive to nanoscale surface features, recent work has used 2D materials like graphene at interfaces to control electrodeposition.

One method for utilizing graphene in electrochemical applications is as a substrate for electrodeposition, with some studies suggesting that metals like Zn (which have a low lattice mismatch with graphene) can grow epitaxially on the graphene, while other studies suggest that the Zn orientation depends on the substrate beneath the graphene. However, most work on crystallographic interactions through graphene has used thermal evaporation of semiconductor materials. Because of these conflicting explanations, the precise role that graphene plays as a substrate for deposition remains unclear, and there is the potential for a variety of different forms of epitaxial growth on graphene, including pinhole epitaxy, remote epitaxy, and van der Waals epitaxy. There are numerous benefits to the use of graphene as a substrate for deposition, including its protection against oxidation to maintain a pristine underlying substrate, but the complex interactions of nanoscale sp² materials at electrochemical interfaces suggest that the role of graphene in electrodeposition remains ambiguous.

Previous work has found that electrodeposition on monolayer graphene yielded deposits that were epitaxial with the underlying metallic substrate, similar to metal-organic chemical vapor deposition (MOCVD) on graphene-coated semiconductors. However, due to the methods used, the mechanism suggested that the deposited metal grew with an orientation relationship to the graphene itself, limiting the metals that could grow epitaxially to those that had similar lattice constants to graphene. Here, using electron backscatter diffraction (EBSD) and transmission electron microscopy (TEM), Zn and Cu electrodeposited on monolayer graphene were found to grow through “remote epitaxy” in crystallographic alignment with the Cu substrate beneath graphene. While these results support the presence of long-range interactions through graphene, investigating electrodeposition on two or more graphene layers with independent relative rotations would confirm that this phenomenon is not limited to monolayer graphene on Cu grown by CVD, which intrinsically forms with a crystallographic relationship between the graphene and Cu substrate. It has been predicted that electronic interactions through graphene during remote epitaxy of semiconductors will be screened with increasing graphene thickness, but the effect of graphene layer number has not been considered for electrodeposited metals, which is key for understanding the role that 2D materials play in influencing local electrochemistry and electrochemical characteristics like charge transfer resistance.

In other words, the present work indicates that the effect is mainly due to the substrate beneath graphene, which allows for a broader range of base layer/deposited metal pairs, with the graphene layer primarily acting as a protective layer for the base layer (preventing oxidation that would inhibit the electronic interactions that make the observed effect possible). While semiconductors have been grown through remote epitaxy where a semiconductor is templated by another semiconductor through a layer of graphene. However, remote epitaxy through electrodeposition has not been previously shown or contemplated. In contrast to the work of others, which suggested any epitaxy during electrodeposition occurs between the graphene and deposited metals, the present methods generate epitaxial growth largely due to the base layer. This is evidenced by the epitaxial electrodeposition occurring for monolayer and bilayer graphene, but not trilayer graphene, and the fact that the graphene is turbostratic,

Demonstrated herein is the influence of the number of graphene layers on the electrochemistry and crystallographic orientation of Zn and Cu electrodeposited from aqueous solutions. The presence of graphene with different layer numbers (mono-, bi-, and trilayer graphene, as well as single crystal graphite) is found to alter electrochemical signatures during electrodeposition. Electron microscopy is used to characterize the morphology of Zn and Cu electrodeposits on graphene with different thickness, demonstrating the effects of graphene interlayers on electrochemical growth. The electrochemical results support the presence of remote epitaxy through mono- and bilayer graphene, while this effect is not present when using trilayer or thicker graphene. DFT shows that charge transfer through thin graphene promotes remote epitaxy via alteration of the electronic environment for the first layer of growing Cu. These results reveal the complex electrochemical behavior of thin graphene, and provide for methods of control over deposited crystallography of various metals through judicious choice of graphene-coated substrate.

### Results and Discussion

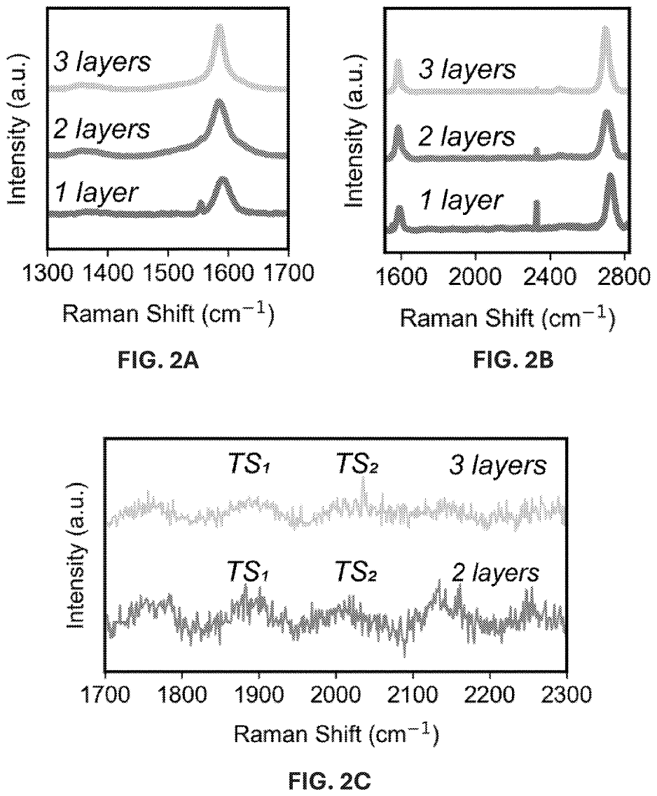

Monolayer graphene grown on Cu foil by chemical vapor deposition (CVD) was used as an electrode and a substrate for graphene transfer. Bi- and trilayer graphene samples on Cu foils were prepared by transferring the purchased monolayer graphene onto Cu foils that already featured a single layer of CVD-grown graphene. The transfer process was performed once to create bilayer graphene and twice to create trilayer graphene. The transfer process was verified on silicon. FIG. 2A shows average Raman spectra from mono-, bi-, and trilayer graphene on the Cu foil. There is little to no D-peak intensity near 1350 cm⁻¹ relative to the G peak intensity near 1600 cm⁻¹, indicating low defect density in the graphene. The ratios between the G and 2D peaks in FIG. 2B are similar for 1-, 2-, and 3-layer graphene. This is inconsistent with AB-stacked graphene, which is the lowest-energy configuration of multilayer graphene. Because our graphene is transferred without intentional alignment, it is thus expected that the graphene layers samples are randomly rotated relative to each other, which is the signature of turbostratic graphene. Turbostratic graphene can be identified by the presence of low-intensity modes in the 1700-2300 cm⁻¹ region of the Raman spectra. FIG. 2C confirms the presence of the two signature modes of turbostratic graphene, labeled TS₁ and TS₂. In addition, there is a low intensity peak around 1750 cm⁻¹, typically labeled the M band, that is not expected to be present in purely turbostratic graphene, but has previously been found to occur in some turbostratic few-layer graphene samples with relatively low I_{2D}/I_{G} ratio. Therefore, we conclude that we have produced low-defect density bi- and trilayer turbostratic graphene. Together with the low-defect density monolayer graphene grown by CVD, we can therefore use these samples to understand the range of thicknesses at which interactions through graphene are expected to occur while minimizing the influence of defects on the morphology of deposits and their nucleation overpotentials.¹⁹ By using turbostratic bi- and trilayer graphene, we also minimize the coupling between layers in the samples.

FIGS. 2A-2C show average Raman spectra (361 acquisitions) taken from a 90 μm² region of as-grown CVD monolayer graphene and bi- and trilayer graphene prepared by polymer-assisted transfer. FIG. 2A shows the location of the D- and G-peaks. FIG. 2B shows the G- and 2D-peak regions. There is a lack of D-peak intensity near 1350 cm⁻¹ in FIG. 2A, indicating graphene with low defect density. The sharp low intensity peak around 1550 cm⁻¹ is an atmospheric O₂ peak. The ratio of the 2D peak to G peak intensity in FIG. 2B is stable for each graphene thickness, which suggests a lack of Bernal stacking. The sharp around 2300 cm⁻¹ is an atmospheric N₂ peak. FIG. 2C shows individual Raman spectra taken from bi- and trilayer graphene showing the presence of turbostratic graphene modes labeled TS₁ and TS₂.

Zn and Cu were electrodeposited on bare Cu, mono-, bi-, and trilayer graphene, as well as on bulk graphite single crystals. Three electrode cells were used with Ag/AgCl reference electrodes, Cu/graphene working electrodes, and Cu or Zn metal as the counter-electrodes. Zn and Cu were electrodeposited under constant current conditions with a current density of 15 mA cm−2 for 40 s (i.e., a capacity of 0.17 mAh cm−2). For electrodeposition of Zn, there was a systematic increase in the nucleation overpotential as the graphene layer thickness increases from single layer to bulk graphite. The nucleation overpotential increases from 39 mV for monolayer graphene to approximately 68 mV for trilayer graphene, and it is over 300 mV for graphite. A higher nucleation overpotential for thicker graphene means that there is a shorter time period over which nuclei form, whereas for small nucleation overpotentials nucleation can happen more readily over longer times during deposition. This suggests that sudden formation of many nuclei is expected for higher nucleation overpotentials. Because of the more complex electrochemical signatures from Cu deposition, classical nucleation and growth analysis was not applied.

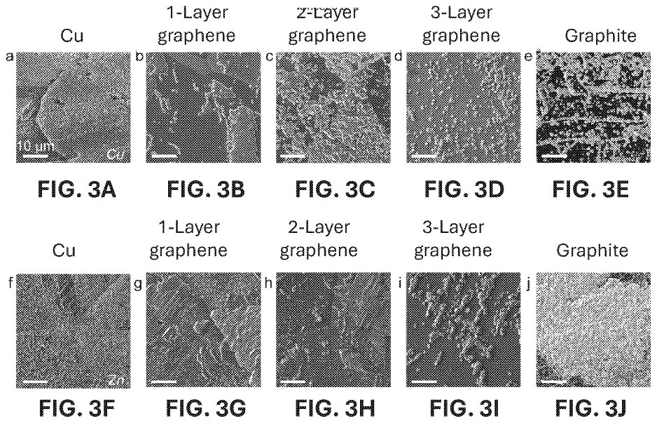

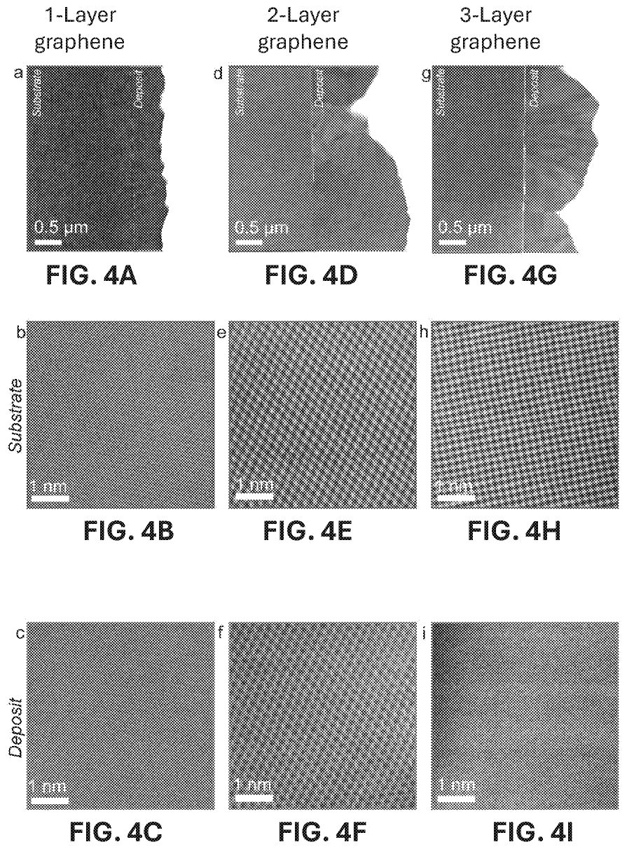

The differences between the Zn and Cu electrochemical curves are reflected in the morphology of the electrodeposited material observed with SEM, as shown in FIGS. 3A-3J. FIGS. 3A and 3F show Cu and Zn deposited on bare Cu substrates. In both cases, the deposited metals cover the entire surface of the metal substrates. Cu and Zn electrodeposited on both mono-and bilayer graphene form relatively large, faceted metal deposits that have distinct morphologies on different Cu grains; the underlying grains are distinguishable by the visible grain boundaries that separate them (deposited Cu is shown in FIGS. 3B, 3C and deposited Zn is shown in FIGS. 3G, 3H). In contrast, Cu and Zn deposited on trilayer graphene exhibit a qualitatively different morphology compared to the material deposited on mono-or bilayer graphene (FIG. 3D, J). Specifically, there are many small deposits scattered across the substrate surface. These deposits have the same morphology across the sample surface independent of the underlying Cu grains, in contrast to deposits on mono- and bilayer graphene/Cu, which feature morphology that depends on the underlying Cu grain structure. The deposited Cu on trilayer graphene (FIG. 3D) appears to be approximately octahedral in shape, while the Zn deposits (FIG. 3I) are boulder-like. Finally, FIGS. 3E and 3J show deposited Cu and Zn, respectively, on single crystal graphite. The deposits show similar morphology to the deposits on trilayer graphene, but they cover more of the graphite surface. Cross-sectional cryogenic focused ion beam (FIB) SEM imaging was used to further investigate the morphology of the Cu deposits on mono-, bi-, and trilayer graphene. From these data, the thicknesses of the Cu deposits are similar on the electrodes with different graphene layer numbers.

We also quantitatively investigated the crystallographic orientation relationships between the Cu or Zn deposits and the underlying Cu substrate using electron backscatter diffraction (EBSD). Crystallographic orientation is the same for the deposited Cu and the underlying Cu substrate, indicating that they are the same orientation. For trilayer graphene, however, EBSD is unable to index the orientation of the deposited material likely because of the small crystallite size of the deposits. This suggests a lack of crystalline registry. Stereographic projection analysis from Zn deposited on monolayer graphene covering a single Cu grain was examined. The close-packed {0002}_{Zn} pole (i.e., the basal plane of the Zn hexagonal structure) overlaps with one of the {111}_{Cu} poles, indicating directional alignment. Full crystallographic alignment is further confirmed by the alignment of the Zn close-packed directions and Cu close-packed directions from the same crystal. The same behavior was exhibited for deposited Zn on bilayer graphene on one underlying Cu grain. The stereographic projection of the Zn poles closely overlaps with the poles of the underlying copper in both close-packed plane orientation and close-packed direction. Stereographic projection analysis is less illustrative for Cu deposition on mono- and bilayer graphene/Cu substrates because the deposit orientation is not discernible from the underlying Cu orientation. Overall, these data suggest that the electrodeposition of Cu and Zn on both mono- and bilayer graphene results in full crystallographic alignment with the underlying Cu substrate (i.e., remote epitaxy).

The crystallographic orientation relationship between the deposited Zn and the underlying Cu substrate on mono- and bilayer graphene is further confirmed by quantifying the angle between the close-packed Zn and Cu planes from many individual grains. The median angle between the Zn and Cu plane normals is 6.7° for monolayer graphene and 6.8° for bilayer graphene, with the majority of the grains clustered around these values. The slight offset is likely due to the {111} faceted surface of the Cu grains, which are primarily {111} and {001} in orientation. The results demonstrate the consistent crystallographic alignment for mono- and bilayer graphene/Cu over many individual crystals.

We also carried out scanning transmission electron microscopy (STEM) to investigate the nature of the interface between the electrodeposits and the substrate. The Cu deposited on monolayer graphene is highly uniform and thinner than the Cu deposited on bi- and trilayer graphene. For mono- and bilayer graphene, there is non-continuous lighter contrast at the interface, while the trilayer graphene sample shows a continuous lighter layer at the interface. This brighter contrast at the interface is due to the presence of graphene of different thicknesses.

Separate high-magnification annular dark-field (ADF) STEM images of the substrates and the deposits grown on those substrates were also taken for the three graphene layer thicknesses. FIGS. 4A, 4D, and 4G are ABF STEM images of cross-sectioned lamella of Cu deposited on mono-, bi-, and trilayer graphene, respectively. (b, c) ADF STEM images of the substrate (b) and deposit (c) for a sample with Cu grown on monolayer graphene/Cu. FIGS. 4E and 4F are ADF STEM images of the substrate (FIG. 4E) and deposit (FIG. 4F) for a sample with Cu grown on bilayer graphene/Cu. FIGS. 4H and 4I are ADF STEM images of the substrate (FIG. 4H) and deposit (FIG. 4I) for a sample with Cu grown on trilayer graphene/Cu. For monolayer (FIGS. 4B, 4C) and bilayer (FIGS. 4E, 4F) graphene, the deposited material and the substrate lattices show identical crystallographic orientation along the [−111] zone axis for the monolayer sample and along the [011] zone axis for the bilayer sample. The Cu deposited on bilayer graphene does show stacking faults, with more defects than the sample grown on monolayer graphene. FIGS. 4H and 4I show high-magnification images of the substrate and deposited material when trilayer graphene is present. The lattices are clearly not aligned in this case. The substrate is aligned along the [001] zone axis, while the region of the deposit shown is aligned along the [011] zone axis.

Further confirmation of registry was also provided by fast Fourier transform (FFT) analysis. Monolayer graphene demonstrated complete overlap and there were similar results for bilayer graphene. For Cu deposited on trilayer graphene, the substrate and deposit do not have the same orientation, as evidenced by the differences in the overlaid FFTs. Further STEM imaging of the trilayer sample revealed that the deposited Cu exhibited significant contrast variations due to polycrystallinity on the micron scale and crystal defects, in contrast to the relatively large grains in the Cu substrate. The selected area electron diffraction (SAED) of the Cu substrate showed a single crystal Cu pattern, while the SAED pattern of both the Cu substrate and Cu deposit for the trilayer graphene sample confirms the randomly-oriented polycrystalline nature of the deposit. This differs from the mono-and bilayer samples, which feature deposits with much larger crystal size that are crystallographically aligned with the substrate through the graphene. Taken together, these imaging and diffraction data confirm the local registry between the substrate and deposit across mono- and bi-layer graphene via remote epitaxy, while there is no crystallographic registry between the substrate and deposit for the three-layer graphene sample. Thus, we conclude that structural alignment is lost with three or more graphene layers.

We performed DFT calculations to understand how the thickness of graphene layers affects the interaction between the deposited Cu and the underlying Cu substrate. After geometry optimization, the distance between the Cu monolayer and the top graphene layer was found to increase from 3.202 Å for monolayer graphene to 3.254 Å for trilayer graphene. We then calculated the energy required to exfoliate the Cu monolayer away from the graphene/Cu(111) substrate, which was found to be 208 meV/Cu, 194 meV/Cu, and 189 meV/Cu for monolayer, bilayer, and trilayer graphene, respectively. These calculations demonstrate that as the graphene thickness increases from monolayer to trilayer, the interaction energy between the Cu deposit and substrate becomes weaker.

To further understand the electronic interaction between the Cu deposit and the substrate through graphene, we plotted the local electronic density of states of the Cu deposit on graphene and graphene/Cu(111). A negative shift of the local density of states was observed when the Cu(111) substrate was included. This effect is evident for monolayer and bilayer graphene, but it disappears for trilayer graphene, corresponding to a negligible electronic interaction between the Cu deposit and the substrate for trilayer graphene. This is in good agreement with the experimentally observed remote epitaxy occurring on monolayer and bilayer graphene but not trilayer or thicker graphene, and it can further be explained by the presence of charge transfer from the Cu substrate to the deposit through the thinner graphene. Electronic charge can be transferred from the Cu substrate to the deposit through monolayer or bilayer graphene. Specifically, Bader charge analysis revealed a charge transfer of 0.152 |e| for monolayer graphene and 0.068 |e| for bilayer graphene. However, for trilayer or thicker graphene, the charge transfer is inhibited, explaining the negligible electronic interaction between the substrate and deposit. As a result, remote epitaxy is not expected to occur in this case.

We have shown that electronic interactions from an underlying Cu substrate through mono- and bilayer graphene facilitate epitaxial growth of electrodeposited Zn and Cu. STEM imaging confirms the agreement in orientation between substrate and deposit near their interface for the mono- and bilayer samples, while the substrate and deposit are not aligned in the case of deposition on trilayer graphene. Analysis of the alignment of close-packed planes and directions in the substrate and deposit from EBSD data further confirms epitaxial electrodeposition for mono- and bilayer graphene samples. DFT calculations reveal electronic interactions between the substrate and deposit through 1- and 2-layer graphene, but inhibited charge transfer through 3-layer graphene. The understanding herein that graphene with multiple layer thicknesses can facilitate crystallographic interactions between underlying metal and electrodeposited material has implications for control of the electrochemical growth processes of metals. Since graphene can prevent substrate oxidation and also be transferred to a wide variety of substrates, a wide variety of substrate materials can be selected to influence the deposition of different deposited metals. Selection of substrates with appropriate crystallographic relationships may enable controlled growth of metals for an array of applications ranging from catalysis to surface coatings. Potential substrates include semiconductor substrates and highly crystalline metal substrates, which can be polycrystalline or single crystalline.

### Methods

### Raman Spectroscopy

Raman spectroscopy and mapping were performed in the Renishaw Raman Spectrometer-Vis/near-IR with a 65 mW 488 nm laser. Raman maps comprised of 361 individual spectra over 90 μm² regions were collected at 50% laser power with an exposure time of 1 second for all samples except for the 1 L graphene sample spectra in FIG. 1b, which was collected with a 5 second exposure time to increase counts. A noise filter was applied to the spectra from the maps and the background subtracted before being averaged. The spectra in FIG. 1c were collected at 100% laser power with an exposure time of 240 seconds, after which the background was subtracted from their spectra. In all cases, a 50× objective was used with a 2400 I/mm grating.

### Graphene Transfer

CVD monolayer graphene on one side of Cu foil was purchased from General Graphene. PMMA (495 A4 Kayaku) was spin coated at 1000 RPM for 60 seconds on the graphene side of the monolayer graphene/Cu foil followed by a cure for 3 min at 100 °C. The backside Cu was then etched in 0.1 M ammonium persulfate solution. After etching overnight, the remaining PMMA/graphene was transferred to four separate DI water baths for cleaning before transferring to the substrate of choice. After transferring, the sample was heated for 15 min at 150 °C. To remove PMMA residue, the sample was left in acetone overnight. Finally, the resulting sample was washed in IPA for 30 min and then washed in DI water for 15 min. To create bilayer graphene, monolayer graphene was transferred to the purchased CVD monolayer graphene on Cu. To create trilayer graphene, monolayer graphene was transferred to bilayer graphene created by PMMA transfer.

### Electrodeposition and Electrochemical Impedance Spectroscopy

Electrodeposition was carried out in three-electrode cells using Ag/AgCl in 1 M KCl reference electrodes purchased from CH Instruments. Zn was electrodeposited by constant current with a current density of 15 mA cm⁻² and a capacity of 0.17 mAh cm⁻². 2.0 M ZnSO₄ (Sigma-Aldrich) was used as the electrolyte for Zn deposition with Zn metal (Sigma-Aldrich) as the counter electrode. Cu was electrodeposited by constant current with a current density of 15 mA cm⁻² and a capacity of 0.17 mAh cm⁻². 20 g of CuSO4-5H₂O (Sigma-Aldrich) was dissolved in 200 mL of 0.5 M H₂SO₄ electrolyte (Supelco) and used as the electrolyte for Cu deposition with Cu metal (MTI) as the counter electrode. The Cu metal used as a counter electrode and substrate deposition was prepared by heating to 1020 °C in a flowing forming gas environment (Ar 95% H₂ 5%) for 1 hour. Kish graphite (2Dsemiconductors) was also used as a substrate for Zn and Cu electrodeposition. EIS was carried out using a Bio-Logic potentiostat with frequencies from 1 MHz to 1 Hz with a 30 mV voltage perturbation for various graphene/Cu electrodes with Zn or Cu counter electrodes in their respective electrolytes. Extraneous impedance values were truncated at high and low frequencies for the Cu sample.

### Scanning Electron Microscopy and FIB-SEM

SEM images were collected at 5 kV using a Tescan Mira3 XM FEG-SEM. Cryogenic FIB cross sectioning of deposted Cu on monolayer, bilayer, and trilayer graphene/Cu was performed using a Thermo Fisher Helios 5 CX dualbeam FIB with a milling current of 0.77 nA and a polishing current of 0.4 nA at −140 °C.

### Electron Backscatter Diffraction

After mounting foils on a 70° holder with no surface milling, scans were collected at 20 kV using the EDAX/AMETEK electron backscatter detector and filtered to only include data with a confidence index of 0.1 or higher for analysis in the Matlab package MTeX.⁴³ Crystallographic models were generated using CrystalMaker® from CrystalMaker Software Ltd (www.crystalmaker.com).

### Scanning Transmission Electron Microscopy and Transmission Electron Microscopy

Aberration-corrected scanning transmission electron microscopy (STEM) images and structural measurements of the FIB-prepared lamellae were collected on a JOEL NEOARM at Oak Ridge National Laboratory at 200 kV. For the selected area electron diffraction experiments a FEI Titan aberration-corrected transmission electron microscope was used at 300 kV.

### Focused Ion Beam Sample Preparation

Samples were prepared by first depositing a conductive protective carbon layer using a sharpie marker dot, before depositing ion beam carbon and tungsten on the Cu-graphene samples. A Hitachi NB5000 FIB instrument was then used to prepare lamellae for transmission electron microscopy (TEM) characterization following established protocols, with a 40 kV beam used to thin down the lamellae to ~300 nm and then a 10 kV beam to thin down to the final electron beam transparent thickness.⁴⁴

### Density Functional Theory

DFT calculations were performed using the Vienna ab initio simulations package (VASP).^{45,46} The electron exchange-correlation was represented by the functional of Perdew, Burke and Ernzerhof (PBE) of generalized gradient approximation (GGA).⁴⁷ The ion-electron interaction was described with the projector augmented wave (PAW) method.⁴⁸ A cutoff energy of 400 eV was used for the plane-wave basis set. The energies were converged with a 1×10⁻⁴ eV tolerance, and the forces were optimized to within 0.03 eV/Å.

Cu/Gr/Cu(111) systems were modeled by different numbers of graphene layers inserted between a Cu monolayer and four layers of Cu(111) in (4×4) lateral cells. During geometry optimization, the Cu monolayer, graphene layers, and top two layers of Cu(111) were allowed to move. A vacuum of 20 Å along the z-direction was used. A (3×3×1) Monkhorst-Pack k-point mesh was used to sample the Brillouin zone. Bader analysis was used to calculate the partial atomic charges.⁴⁹ The DFT-D3 method was used to include the van der Waals interactions.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. In an embodiment, “about 0 ” can refer to 0, 0.001, 0.01, or 0.1. In an embodiment, the term “about” can include traditional rounding according to significant figures of the numerical value. In addition, the phrase “about ‘x’ to ‘y’” includes “about ‘x’ to about ‘y’”.

Therefore, at least the following is claimed:

1. A method of controlling epitaxial metal growth, the method comprising:
selecting a metal;
selecting a low-defect density turbostratic graphene substrate based on a desired crystallographic influence on the metal, the substrate comprising a base layer and a graphene bilayer or a graphene monolayer deposited on the base layer; and
electrodepositing the metal on the graphene bilayer or the graphene monolayer.

2. The method of claim 1, wherein the metal is copper or zinc.

3. The method of claim 1, wherein the base layer is copper foil.

4. The method of claim 1, wherein the electrodeposited metal has a same crystallographic orientation as that of the base layer.

5. The method of claim 1, wherein an electrochemical interaction between the metal and the base layer is different between a substrate comprising the graphene bilayer and substrate comprising the graphene monolayer deposited on the base layer.

6. The method of claim 1, wherein the method further comprises forming the graphene bilayer by transferring, via polymer-assisted transfer, a second monolayer of graphene onto the graphene monlolayer.

7. The method of claim 1, wherein the graphene monolayer comprises a single layer of chemical vapor deposition-grown graphene on the base layer, and wherein the base layer is copper foil.

8. The method of claim 1, wherein the graphene bilayer comprises a first graphene layer and a second graphene layer each having a relative rotation independent to one another.

9. The method of claim 1, wherein the depositing is electrodepositing.

10. A metal thin film comprising:
a low-defect density turbostratic graphene substrate, the substrate comprising a base layer and a graphene bilayer or a graphene monolayer deposited on the base layer; and
a metal layer electrodeposited on the graphene bilayer or the graphene monolayer, wherein the metal is crystallographically aligned to the base layer.

11. The metal thin film of claim 10, wherein the metal is copper or zinc.

12. The metal thin film of claim 11, wherein the base layer is copper foil.

13. A method of making a metal thin film, the method comprising:
selecting a metal;
providing a graphene substrate, the substrate comprising a first graphene monolayer grown on a base layer by chemical vapor deposition; and
electrodepositing the metal on the first graphene monolayer.

14. The method of claim 13, further comprising:
prior to the electrodepositing, forming a graphene bilayer by transferring a second graphene monolayer onto the first monolayer graphene to obtain a low-defect density turbostratic graphene substrate, and wherein the metal is electrodeposited on the graphene bilayer.

15. The method of claim 13, wherein the metal is copper or zinc.

16. The method of claim 13, wherein the base layer is copper foil.

17. The method of claim 13, wherein the electrodeposited metal has a same crystallographic orientation as that of the base layer.

18. The method of claim 13, wherein the transferring is a polymer-assisted transfer.

19. The method of claim 14, wherein the first graphene monolayer and the second graphene monolayer have a relative rotation independent to one another.

20. The method of claim 14, further comprising transferring one or more graphene monolayers onto the graphene bilayer prior to the electrodepositing.
